(19) United States
(12) Patent Application Publication
(10) Pub. No.: US 2024/0105612 A1
(43) Pub. Date: Mar. 28, 2024

(54) BACKSIDE POWER DISTRIBUTION NETWORK AND BACKSIDE SINGLE CRYSTAL TRANSISTORS

(71) Applicant: INTERNATIONAL BUSINESS MACHINES CORPORATION, Armonk, NY (US)

(72) Inventors: Ruilong Xie, Niskayuna, NY (US); Nicholas Alexander Polomoff, Hopewell Junction, NY (US); Brent A. Anderson, Jericho, VT (US); Chih-Chao Yang, Glenmont, NY (US)

(21) Appl. No.: 17/954,514

(22) Filed: Sep. 28, 2022

(51) Int. Cl. H01L 23/528; H01L 21/768; H01L 23/48; H01L 29/417

(52) U.S. Cl. CPC H01L 23/5286; H01L 21/76898; H01L 23/481; H01L 29/41725

(57) ABSTRACT

A semiconductor structure is presented including a device layer having a plurality of active devices, back-end-of-line (BEOL) components disposed under the device layer, a power distribution network (PDN) disposed over the device layer, and backside transistors disposed on a single crystal silicon (Si) layer disposed over the PDN. A through silicon via (TSV) extends from the backside transistors disposed on the single crystal Si layer through the BEOL. An upper TSV (uTSV) extends from the PDN through the backside transistors disposed on the single crystal Si layer to additional interconnects.

### BACKGROUND

The present invention relates generally to semiconductor devices, and more specifically, to a method and structure of forming a backside power distribution network and backside single crystal transistors.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). While chipmakers are moving ahead with technology generations, maintaining the same timeline for scaling transistors in the front-end-of-line (FEOL), contacts and interconnects in the middle-of-line (MOL) and back-end-of-line (BEOL) has become challenging.

### SUMMARY

In accordance with an embodiment, a semiconductor structure is provided. The semiconductor structure includes a device layer including a plurality of active devices, back-end-of-line (BEOL) components disposed under the device layer, a power distribution network (PDN) disposed over the device layer, and backside transistors disposed on a single crystal silicon (Si) layer disposed over the PDN.

In accordance with another embodiment, a semiconductor structure is provided. The semiconductor structure includes a power distribution network (PDN) disposed between a device layer and back-end-of-line (BEOL) components and backside transistors disposed over the PDN.

In accordance with yet another embodiment, a method for forming a semiconductor structure is provided. The method includes forming a power distribution network (PDN) over a single crystal silicon (Si) layer, an etch stop layer, and a substrate, disposing bonding dielectric layers over the PDN, forming a device layer over the bonding dielectric layers, constructing BEOL components over the device layer, bonding a carrier wafer, flipping the carrier wafer, removing the substrate and the etch stop layer, forming backside transistors over the single crystal Si layer, and forming additional interconnects and through silicon vias (TSVs).

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure where a silicon (Si) layer and an etch stop layer are formed over a substrate, in accordance with an embodiment of the present invention;

FIG. 2 is a cross-sectional view of the semiconductor structure of FIG. 1 where an interlayer dielectric (ILD) is deposited and a power distribution network (PDN) is formed therein, in accordance with an embodiment of the present invention;

FIG. 3 is a cross-sectional view of the semiconductor structure of FIG. 2 where a semiconductor layer is bonded over the PDN through a dielectric-to-dielectric bonding process, in accordance with an embodiment of the present invention;

FIG. 4 is a cross-sectional view of the semiconductor structure of FIG. 3 where a patterning process takes place to form fins, in accordance with an embodiment of the present invention;

FIG. 5 is a cross-sectional view of the semiconductor structure of FIG. 4 where a device layer is formed, which includes gates (not shown), source/drain (S/D) epi regions, source/drain contacts, gate contacts (not shown), and VBPR contacts, in accordance with an embodiment of the present invention;

FIG. 6 is a cross-sectional view of the semiconductor structure of FIG. 5 where back-end-of-line (BEOL) processing takes place and a carrier wafer is bonded to the BEOL, in accordance with an embodiment of the present invention;

FIG. 7 is a cross-sectional view of the semiconductor structure of FIG. 6 where the wafer is flipped and the substrate is selectively removed, in accordance with an embodiment of the present invention;

FIG. 8 is a cross-sectional view of the semiconductor structure of FIG. 7 where the etch stop layer is selectively removed, in accordance with an embodiment of the present invention;

FIG. 9 is a cross-sectional view of the semiconductor structure of FIG. 8 where backside transistors (e.g., can be used for power gating) are formed on the single crystal silicon layer, in accordance with an embodiment of the present invention; and

FIG. 10 is a cross-sectional view of the semiconductor structure of FIG. 9 where additional interconnections and through silicon vias (TSVs) are formed, in accordance with an embodiment of the present invention.

Throughout the drawings, same or similar reference numerals represent the same or similar elements.

### DETAILED DESCRIPTION

Embodiments in accordance with the present invention provide methods and devices for constructing a power distribution network (PDN) in a dielectric, the PDN confined between two layers of devices over a single crystal silicon (Si) layer.

According to Moore's Law, transistor dimensions scale down by 0.7× every two years. To maintain this scaling path, the industry has moved from planar metal oxide semiconductor field effect transistors (MOSFETs) to a FinFET transistor architecture. In a FinFET, the channel between the source and drain terminals is in the form of a fin, and the gate wraps around this 3D channel, thus providing control from three sides of the channel. This multi-gate structure can eliminate short-channel effects, which started to degrade the transistor's performance at reduced gate length.

To keep up with area scaling in the front-end-of-line (FEOL), back-end-of-line (BEOL) dimensions have been reduced at an accelerated pace leading to ever smaller metal pitches and reduced cross-sectional areas of the wires. Today, most critical local interconnects (M1 and M2) have metal pitches as tight as 40 nm or below. Copper (Cu)-based dual damascene is the workhorse process flow for making the interconnects. A dual-damascene flow starts with the deposition of a low-k dielectric material on a structure. These low-k films are designed to reduce the capacitance and the delay in the chips. Subsequently, vias and trenches are formed. Recently all leading logic manufacturers have announced the use of extreme ultraviolet (EUV) lithography in their technology in order to remain cost effective at tight pitches. After patterning, a metallic barrier layer is added to prevent Cu atoms from migrating into the low-k materials. After coating the barrier layers by a liner and Cu seed, the structure is electroplated by Cu and then a chemical mechanical polishing (CMP) step is applied to complete the dual damascene module.

Routing congestion and a dramatic RC delay (resulting from an increased resistance-capacitance (RC) product) have become bottlenecks for further interconnect scaling, driving the need for introducing new materials and integration schemes in the BEOL.

Connection between the FEOL and BEOL is provided by the middle-of-line (MOL). For a long time, this MOL was organized as a single layer contact, but nowadays it is expanding into several layers. These layers carry the electrical signals from the transistor's source, drain and gate to the local interconnects, and vice versa.

At the transistor side, the source/drain contact resistance has become an important concern for the chip industry. With shrinking transistor dimensions, the area available for making the contacts has decreased accordingly. This has caused a dramatic increase of the source/drain contact resistance, which is proportional to this contact area.

To further improve the connectivity in the MOL, structural scaling boosters have been introduced. One example is the self-aligned gate contact, which allows the placement of the gate contact directly on top of the active device. This has enabled a more flexible gate access and a reduction of the overall contact area.

In the MOL, this connectivity evolution will continue, allowing other implementations of the MOL layers depending on the connection needs between the devices and the interconnects. For example, another emerging booster is the backside power rail (BPR). Power rails are part of the power delivery network and are traditionally implemented in the chip's BEOL. BPRs on the contrary are built under the chip's FEOL layer to help free up routing resources for the interconnects. The BPRs can be wired to FEOL devices through via-to-backside power rail (VBPR) contacts, in which the VBPR stitches with the MOL contacts. Conventionally, a BEOL transistor for special functions, such as power gating, is fabricated on polycrystal or amorphous materials. When a backside power distribution network (PDN) is introduced, there's an opportunity to integrate high quality single crystal transistors at the backside of the wafer to achieve better performance than conventional BEOL transistors.

The exemplary embodiments of the present invention introduce methods and devices for constructing a PDN in a dielectric, the PDN confined between two layers of devices under a single crystal silicon (Si). The method includes forming the PDN over a single crystal Si layer, etch stop layer and a substrate, bonding the channel layers over the PDN, forming a device layer and an MOL connection, forming BEOL interconnects, bonding a carrier wafer, flipping the wafer, removing the substrate, removing the etch stop layer, forming a backside power transistor over the single crystal Si layer, and forming additional interconnects and TSVs, thus resulting in the integration of the backside power transistors with BPR/BSPDN.

Examples of semiconductor materials that can be used in forming such structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

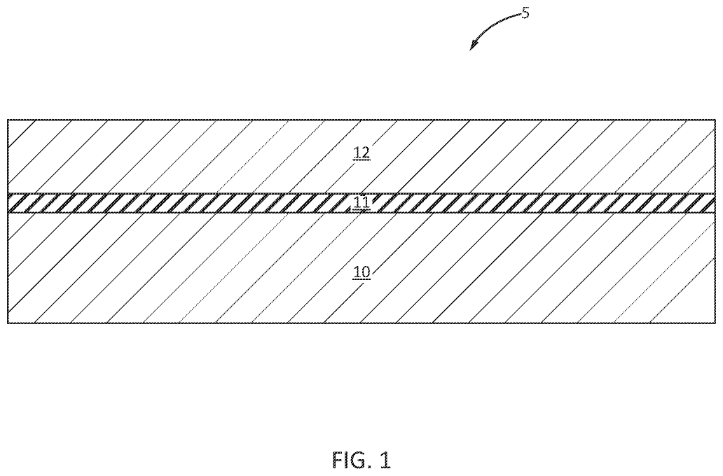

FIG. 1 is a cross-sectional view of a semiconductor structure where a silicon (Si) layer and an etch stop layer are formed over a substrate, in accordance with an embodiment of the present invention.

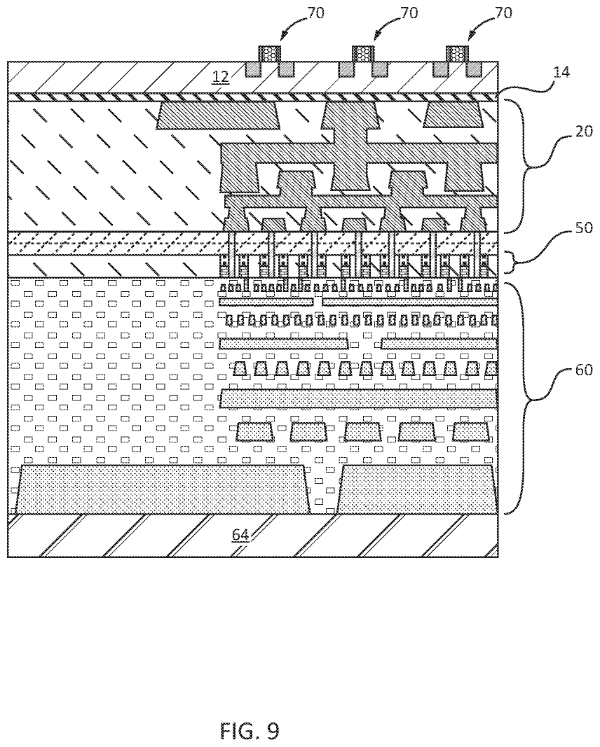

In various example embodiments, in structure 5, a single crystal silicon (Si) layer 12 and an etch stop layer 11 are formed over a substrate 10. The etch stop layer 11 can be, e.g., a silicon germanium (SiGe) layer. Backside transistors 70 will eventually be formed on the single crystal Si layer 12 (FIG. 9).

In one or more embodiments, the substrate 10 can be a semiconductor or an insulator with an active surface semiconductor layer. The substrate 10 can be crystalline. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, Al₂O₃, SiO₂, GaAs, SiC, or SiGe. The substrate 10 can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate 10 can also have other layers forming the substrate 10, including high-k oxides and/or nitrides. In one or more embodiments, the substrate 10 can be a silicon wafer. In an embodiment, the substrate 10 is a single crystal silicon wafer.

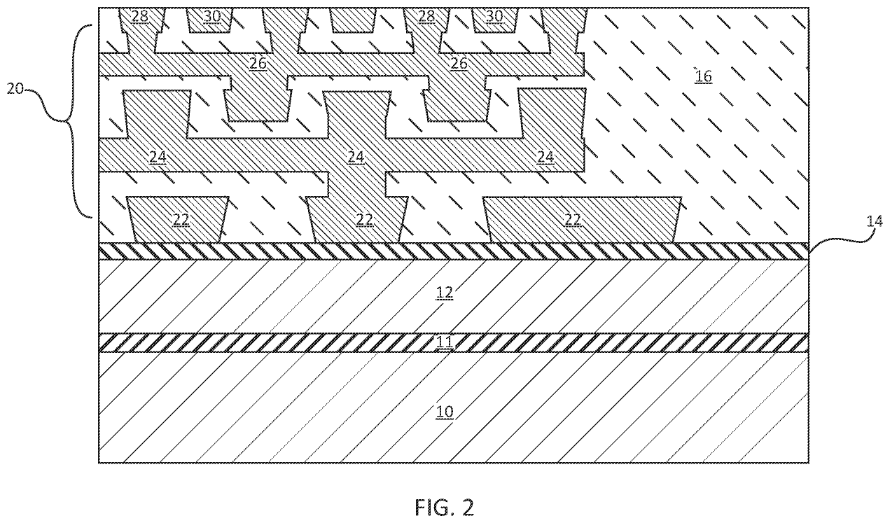

FIG. 2 is a cross-sectional view of the semiconductor structure of FIG. 1 where an interlayer dielectric (ILD) is deposited and a power distribution network (PDN) is formed therein, in accordance with an embodiment of the present invention.

In various example embodiments, another etch stop layer 14 and an interlayer dielectric (ILD) 16 are deposited. A power distribution network (PDN) 20 is formed within the ILD 16. The PDN 20 includes metal lines, such as metal lines 22, 24, 26, 28, 30. The PDN 20 can be presented in a variety of different configurations. The metals lines 28 can be VDD power rails, which is the operating voltage of the chip and the metals lines 30 can be VSS power rails, which is the ground point.

Non-limiting examples of suitable conductive materials for the metal lines 22, 24, 26, 28, 30 include an adhesion metal liner, such as TiN, TaN, and conductive metal fill, such as Al, W, Co, Ru, Cu, Mo, etc. The conductive material can further include dopants that are incorporated during or after deposition. The conductive metal can be deposited by a suitable deposition process, for example, CVD, PECVD, PVD, plating, thermal or e-beam evaporation, and sputtering.

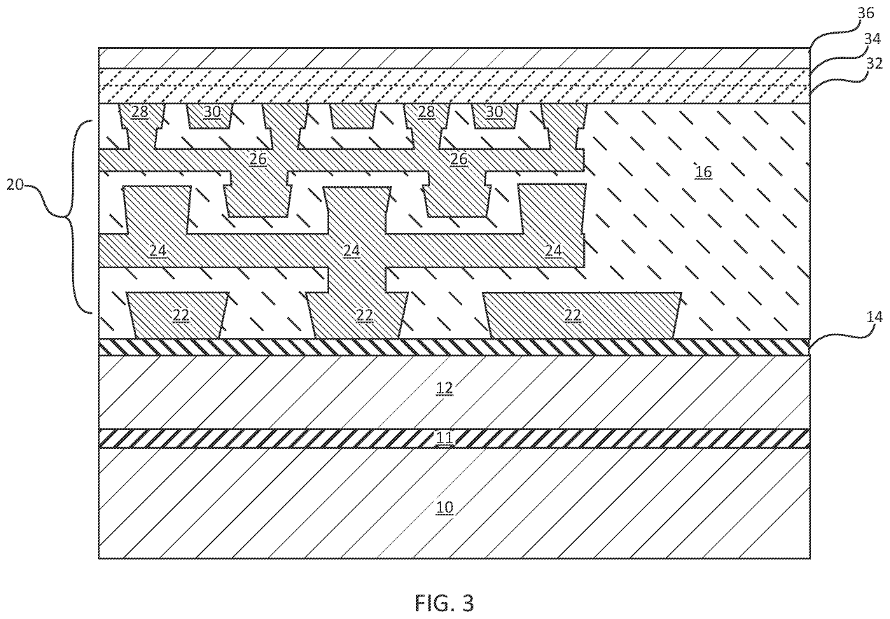

FIG. 3 is a cross-sectional view of the semiconductor structure of FIG. 2 where a semiconductor layer is bonded over the PDN through a dielectric-to-dielectric bonding process, in accordance with embodiments of the present invention.

In various example embodiments, a bonding dielectric layer 32 is deposited over the PDN 20 and a bonding dielectric layer 34 is deposited over another substrate layer 36 (e.g., a silicon (Si) substrate).

The bonding dielectric layers 32, 34 can be at a thickness of 20 nm to lum each.

Bonding can be effected by annealing at an elevated temperature in an amount effective to enhance oxide-to-oxide bonding. After the wafer bonding process, the substrate layer 36 is thinned down to the thickness that is suitable for device fabrication.

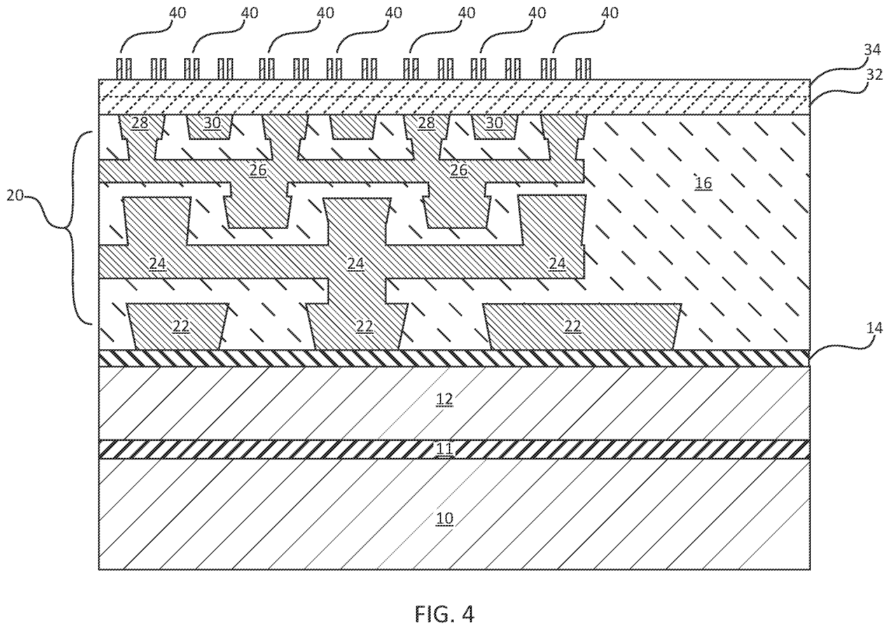

FIG. 4 is a cross-sectional view of the semiconductor structure of FIG. 3 where a patterning process takes place to form fins, in accordance with an embodiment of the present invention.

In various example embodiments, a patterning process takes place to form the fins 40. The fins 40 can be dual fins equally spaced apart from each other or any number of fins that are suitable for the circuit requirement. It is noted that FinFETs are used for illustrative purposes, however, the device layer can also be a nanosheet or a planar device.

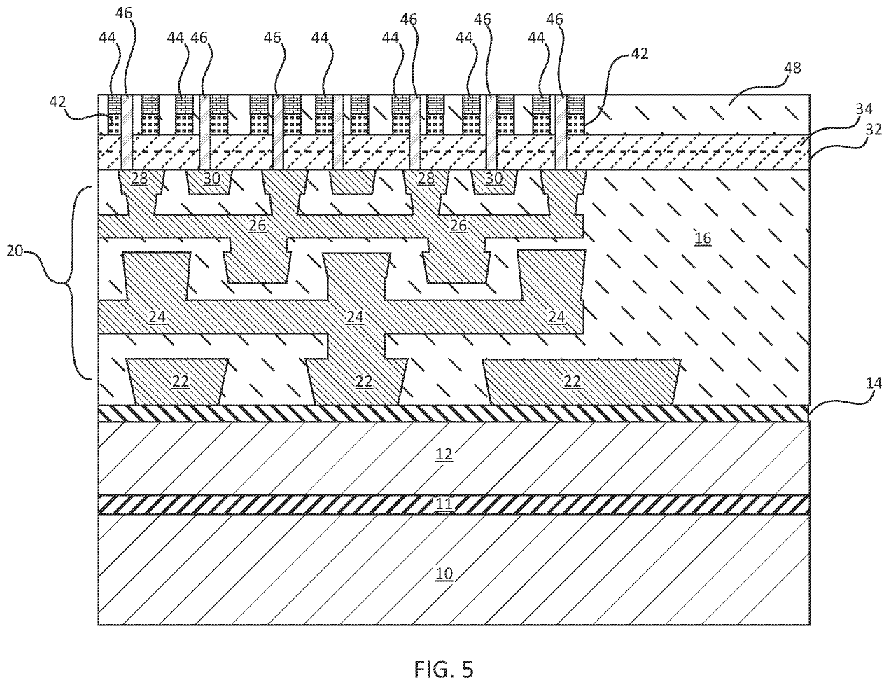

FIG. 5 is a cross-sectional view of the semiconductor structure of FIG. 4 where a device layer is formed, which includes gates (not shown), source/drain (S/D) epi regions, source/drain contacts, gate contacts (not shown), and VBPR contacts, in accordance with an embodiment of the present invention.

In various example embodiments, S/D epi regions 42 are formed over the bonding dielectric layer 34. Source/drain (S/D) contacts 44 are formed over the S/D epi regions 42. Via-to-BPR (VBPR) contacts 46 are formed to the very first metals lines 28, 30 of the PDN 20. All these components are formed within a dielectric layer 48. This region can be referred to as a device layer 50.

Regarding various dielectrics or dielectric layers (such as the dielectric layer 48) discussed herein, the dielectrics can include, but are not limited to, SiO₂, SiN, SiOCN, SiOC, SiBCN, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectrics can be conformally deposited using atomic layer deposition (ALD) or, chemical vapor deposition (CVD). Variations of CVD processes suitable for forming the dielectrics include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

The S/D epi regions 42 can be of the same or different materials for pFET and nFET devices, and can be either in-situ doped with appropriate polarity dopants (B for pFET and P for nFET devices) or doped by ion implantation.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The etching can include a dry etching process such as, for example, wet etch, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

The manufacturing of leading-edge logic chips can be subdivided in three separate blocks, that is, the front-end-of-line (FEOL), the middle-of-line (MOL) and the back-end-of-line (BEOL). Regarding FIGS. 1-5, they include FEOL and MOL processing.

The FEOL covers the processing of the active parts of the chips, that is, the transistors that reside on the bottom of the chip. The transistor serves as an electrical switch and uses three electrodes for its operation, that is, a gate, a source, and a drain. Electrical current in the conduction channel between source and drain can be switched “on” and “off,” an operation that is controlled by the gate voltage.

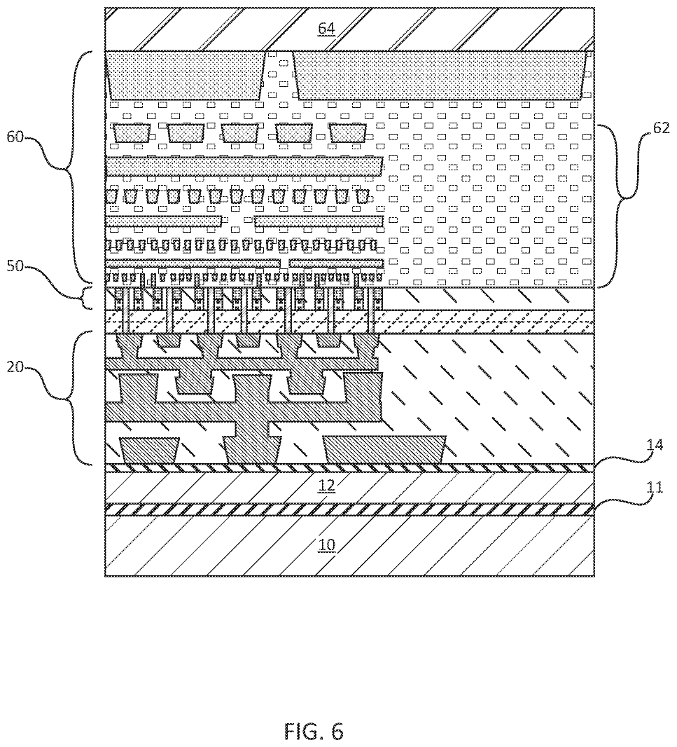

FIG. 6 shows additional formation of the BEOL 60 over the device layer 50. The BEOL refers to the interconnects that reside in the top part of the chip. Interconnects are complex wiring schemes that distribute clock and other signals, provide power and ground, and transfer electrical signals from one transistor to another. The BEOL is organized in different metal layers, local (Mx), intermediate, semi-global and global wires. The total number of layers can be as many as 15, while the usually number of Mx layers ranges between 3 and 6. Each of these layers includes (unidirectional) metal lines that are organized in regular tracks, as well as dielectric materials. They are interconnected vertically by means of via structures that are filled with metal.

The FEOL and the BEOL are tied together by the MOL. The MOL is usually made up of tiny metal structures that serve as contacts to the transistor's source, drain and gate. These structures connect to the local interconnect layers of the BEOL. While cell size is scaling, the number of pins to connect to remains roughly the same, meaning that access to them is more challenging. In the instance case, the VBPR contacts 46 help improve connectivity within the MOL. Connection between the FEOL and BEOL is provided by the MOL. For a long time, this MOL was organized as a single layer contact, but nowadays it is expanding into several layers. These layers carry the electrical signals from the transistor's source, drain and gate to the local interconnects, and vice versa. At the transistor side, the source/drain contact resistance has become an important concern for the chip industry. With shrinking transistor dimensions, the area available for making the contacts has decreased accordingly. This has caused a dramatic increase of the source/drain contact resistance, which is proportional to this contact area. To further improve the connectivity in the MOL, the exemplary embodiments of the present invention present the PDN 20 in the ILD 16 (and above the MOL with active devices) confined between two layers of devices over the single crystal Si layer 12 to improve chip performance, as described below with reference to FIGS. 6-10.

FIG. 6 is a cross-sectional view of the semiconductor structure of FIG. 5 where back-end-of-line (BEOL) processing takes place and a carrier wafer is bonded to the BEOL, in accordance with an embodiment of the present invention.

In various example embodiments, BEOL processing takes place to form the BEOL 60 with components 62 therein. A carrier wafer 64 is bonded to the BEOL 60. The BEOL 60 is formed over the device layer 50, which includes active devices and the MOL. The device layer 50 is positioned between the PDN 20 and the BEOL 60. The top of the device layer 50 directly contacts the BEOL 60, whereas the bottom of the device layer 50 directly contacts the bonding dielectric layer 34. The device layer 50 includes the VBPR contacts 46 that directly contact portions of the PDN 20.

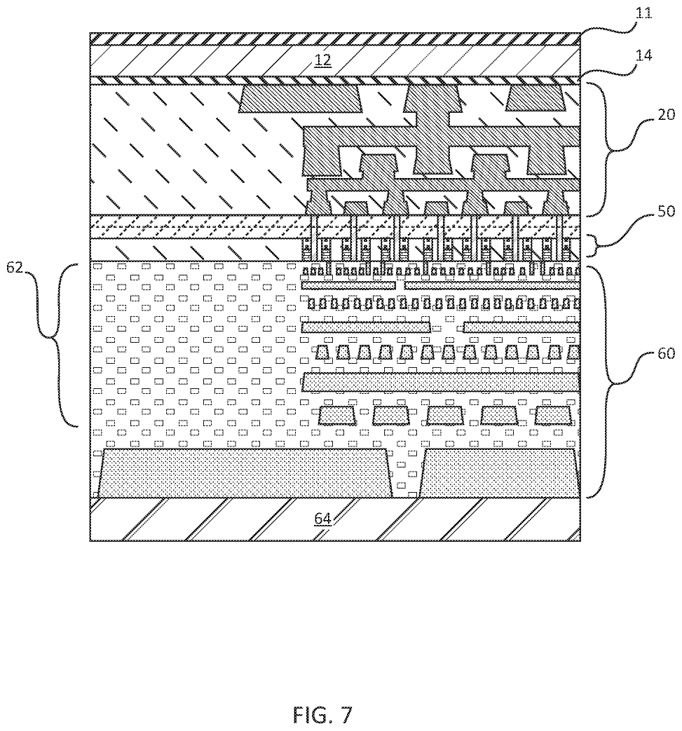

FIG. 7 is a cross-sectional view of the semiconductor structure of FIG. 6 where the wafer is flipped and the substrate is selectively removed, in accordance with an embodiment of the present invention.

In various example embodiments, the wafer is flipped and the substrate 10 is selectively removed.

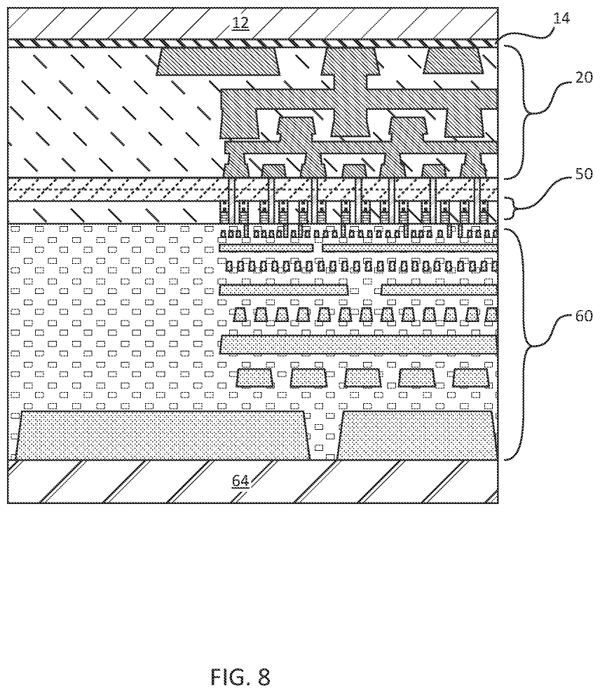

FIG. 8 is a cross-sectional view of the semiconductor structure of FIG. 7 where the etch stop layer is selectively removed, in accordance with an embodiment of the present invention.

In various example embodiments, the etch stop layer 11 is selectively removed.

FIG. 9 is a cross-sectional view of the semiconductor structure of FIG. 8 where backside transistors (e.g., can be used for power gating) are formed on the single crystal silicon layer, in accordance with an embodiment of the present invention.

In various example embodiments, backside transistors 70 are formed on the single crystal Si layer 12. The backside transistors 70 include a gate and source/drain (S/D) regions.

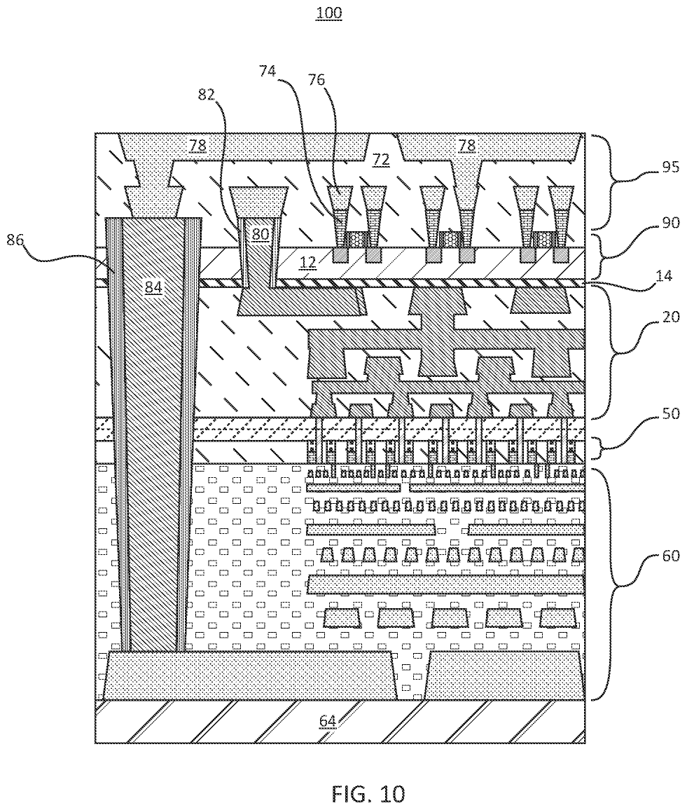

FIG. 10 is a cross-sectional view of the semiconductor structure of FIG. 9 where additional interconnections and through silicon vias (TSVs) are formed, in accordance with an embodiment of the present invention.

In various example embodiments, additional connections and through silicon vias (TSVs) are formed to construct the final semiconductor structure 100. In particular, a backside transistor over a single crystal Si area 90 is formed and an additional connections and TSVs area 95 is formed over the backside transistor over single crystal Si area 90. A TSV 84 is formed from the BEOL 60 to the additional connections and TSVs area 95. A dielectric liner 86 is formed on opposed ends of the TSV 84. An upper TSV (uTSV) 80 is formed from the PDN 20 to the additional connections and TSVs area 95. A dielectric liner 82 is formed on opposed ends of the uTSV 80. The additional connections and TSVs area 95 includes an ILD 72, source/drain (S/D) contacts 74 formed to the backside transistors 70 and a metal line 76 formed over the S/D contacts 74. Metal lines 78 are also formed within the ILD 72.

Therefore, the final semiconductor structure 100 includes the device layer 50 having a plurality of active devices, the BEOL 60 disposed under the device layer 50, the PDN 20 disposed over the device layer 50, and the backside transistors 70 formed on the single crystal Si layer 12 disposed over the PDN 20. Stated differently, the PDN 20 is disposed between the device layer 50 and the BEOL 60, and the backside transistors 70 are disposed over the PDN 20.

The bonding dielectric layers 32, 34 are disposed directly between the device layer 50 and the PDN 20. The TSV 84 extends from the backside transistors 70 formed on the single crystal Si layer 12 through the BEOL 60. The uTSV 80 extends from the PDN 20 through the backside transistors 70 formed on the single crystal Si layer 12. Moreover, the VBPR contacts 46 of the device layer 50 extend through the bonding dielectric layers 32, 34 to the PDN 20. The etch stop layer 14 is disposed directly between the PDN 20 and the backside transistors 70 formed on the single crystal Si layer 12.

In conclusion, the exemplary embodiments of the present invention present methods and devices for constructing a PDN in a dielectric or ILD, the PDN confined between two layers of devices over a single crystal Si layer. The semiconductor structure includes a device layer, a BEOL interconnect under the device layer, the PDN over the device layer, and the backside transistors formed on the single crystal Si layer and over the PDN.

Regarding FIGS. 1-10, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed. Patterning also includes electron-beam lithography.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for forming a backside power distribution network and backside single crystal transistors (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a device layer including a plurality of active devices;
back-end-of-line (BEOL) components disposed under the device layer;
a power distribution network (PDN) disposed over the device layer; and
backside transistors disposed on a single crystal silicon (Si) layer disposed over the PDN.

2. The semiconductor structure of claim 1, wherein bonding dielectric layers are disposed directly between the device layer and the PDN.

3. The semiconductor structure of claim 1, wherein a through silicon via (TSV) extends from the backside transistors disposed on the single crystal Si layer through the BEOL.

4. The semiconductor structure of claim 1, wherein an upper TSV (uTSV) extends from the PDN through the backside transistors disposed on the single crystal Si layer.

5. The semiconductor structure of claim 1, wherein via-to-BPRs (VBPRs) of the device layer extend through bonding dielectric layers to the PDN.

6. The semiconductor structure of claim 1, wherein source/drain (S/D) contacts are disposed over the backside transistors disposed on the single crystal Si layer.

7. The semiconductor structure of claim 1, wherein an etch stop layer is disposed directly between the PDN and the backside transistors disposed on the single crystal Si layer.

8. A semiconductor structure comprising:
a power distribution network (PDN) disposed between a device layer and back-end-of-line (BEOL) components; and
backside transistors disposed over the PDN.

9. The semiconductor structure of claim 8, wherein the backside transistors are disposed on a single crystal silicon (Si) layer.

10. The semiconductor structure of claim 9, wherein a through silicon via (TSV) extends from the backside transistors disposed on the single crystal Si layer through the BEOL.

11. The semiconductor structure of claim 9, wherein an upper TSV (uTSV) extends from the PDN through the backside transistors disposed on the single crystal Si layer.

12. The semiconductor structure of claim 9, wherein source/drain (S/D) contacts are disposed over the backside transistors disposed on the single crystal Si layer.

13. The semiconductor structure of claim 9, wherein an etch stop layer is disposed directly between the PDN and the backside transistors disposed on the single crystal Si layer.

14. The semiconductor structure of claim 8, wherein bonding dielectric layers are disposed directly between the device layer and the PDN.

15. The semiconductor structure of claim 14, wherein via-to-BPRs (VBPRs) of the device layer extend through the bonding dielectric layers to the PDN.

16. A method comprising:
forming a power distribution network (PDN) over a single crystal silicon (Si) layer, an etch stop layer, and a substrate;
disposing bonding dielectric layers over the PDN;
forming a device layer over the bonding dielectric layers;
constructing BEOL components over the device layer;
bonding a carrier wafer;
flipping the carrier wafer;
removing the substrate and the etch stop layer;
forming backside transistors over the single crystal Si layer; and
forming additional interconnects and through silicon vias (TSVs).

17. The method of claim 16, wherein one TSV of the TSVs extends from the backside transistors formed on the single crystal Si layer through the BEOL components.

18. The method of claim 16, wherein one TSV of the TSVs extends from the PDN through the backside transistors formed on the single crystal Si layer to the additional interconnects.

19. The method of claim 16, wherein source/drain (S/D) contacts are disposed over the backside transistors formed on the single crystal Si layer.

20. The method of claim 16, wherein via-to-BPRs (VBPRs) of the device layer extend through the bonding dielectric layers to the PDN.
